(19) United States
(12) Patent Application Publication
(10) Pub. No.: US 2004/0256150 A1
(43) Pub. Date: Dec. 23, 2004

(54) Nonconducting substrate, forming a strip or a panel, on which a multiplicity of carrier elements are formed

(75) Inventors: Bernd Barchmann, Regensburg (DE); Erik Heinemann, Regensburg (DE); Josef Heitzer, Bach/Donau (DE); Frank Puschner, Kelheim (DE)

Correspondence Address: DARBY & DARBY P.C., P. O. BOX 5257, NEW YORK, NY, 10150-5257, US

(73) Assignee: Infineon Technologies AG, Munich (DE)

(21) Appl. No.: 10/803,174

(22) Filed: Mar. 16, 2004

Related U.S. Application Data
(63) Continuation of application No. PCT/DE02/03284, filed on Sep. 5, 2002.

(30) Foreign Application Priority Data
Sep. 17, 2001 (DE) 101 45 752.9

(51) Int. Cl. H01L 21/00; H05K 1/03

(52) U.S. Cl. 174/266; 174/255

(57) ABSTRACT

A nonconducting substrate forming a strip or a panel on which a plurality of carrier elements having respective boundary lines are formed. The substrate includes a contact side, an insertion side opposite the contact side, and a conducting insertion-side metallization provided on the insertion side. The insertion-side metallization is formed such that an electrical connection can take place by flip-chip bonding between contact points of an integrated circuit to be applied to the insertion side and the insertion-side metallization.

### CROSS-REFERENCE TO RELATED APPLICATION

This application is a continuation of International Patent Application Serial No.

PCT/DE02/03284, filed Sep. 5, 2002, which published in German on Apr. 3, 2003 as WO 03/028044 A3, and which is incorporated herein by reference in its entirety.

### FIELD OF THE INVENTION

The present invention relates to a nonconducting substrate, forming a strip or a panel, on which a multiplicity of carrier elements are formed.

### BACKGROUND OF THE INVENTION

A carrier element which is cut out from such a substrate is known from FIGS. 8 and 9 of EP 0 671 705 A2. The carrier element in said publication is intended for incorporation into a chip card which can be operated both with contacts by means of a number of contact areas and without contacts by means of an antenna coil, for example by means of transformer coupling. Carrier elements for chip cards serve for mechanically securing the semiconductor chip and also have the contact areas necessary for the electrical bonding of the chip. They are used both in chip cards of the purely with-contacts type, so that access to the semiconductor chip is possible only via the contact area, and in what are known as combined cards, in which contactless access is additionally possible by means of conductor loops in the card and/or on the carrier element or the semiconductor chip. For this purpose, the conductor loops are connected to coil terminals of the semiconductor chip.

The carrier elements are usually not produced individually but in large numbers on a long strip or a panel of a large area made of a nonconducting material. This strip—referred to hereafter as the substrate—or the panel is additionally structured, for example by punching cutouts, and then laminated on one side with a copper foil, which is subsequently structured, for example by etching, so that the contact areas for the individual carrier elements are formed. All the conducting structures are initially still connected to one another in an electrically conducting manner by narrow lines, to allow the surface to undergo electroplating treatment.

The semiconductor chips are attached on the side of the substrate lying opposite from the contact areas and are electrically connected to the contact areas by means of bonding wires through the cutouts. Before a functional test of the semiconductor chips, which takes place while they are still in the strip or panel, the narrow lines are severed by means of punching, so that the contact areas are electrically isolated from one another.

In the case of the carrier element of EP 0 671 705 A2, the electrical connection between the semiconductor chip and the contact areas is realized by means of wire connections (bonding wires). When the chip cards are dispatched by mail, they are transported and sorted by means of letter sorting installations. In the process, the carrier elements located in the chip card are subjected to a high level of mechanical bending stress, which is caused by changes in direction within the letter sorting installation. On account of the high throughput rates, frequent changes of direction via movable rollers, which usually have a diameter of around 40 mm, and other design features of a letter sorting installation, the carrier element is also subjected to very high kinetic forces.

The forces occurring may lead in an individual case to either the semiconductor chip or the wire connections being damaged as the chip card runs through the letter sorting installation. It is therefore customary to neutralize the forces occurring by increasing the module bending resistance in the region of the semiconductor chip and wire connections. To avoid damaging the semiconductor chip, DE 298 18 829 U1 proposes applying an area-covering coating to the chip card outside the actual semiconductor chip area, in order to avoid transferring the elastic pressing pressure of a transport roller of the letter sorting installation onto the chip area.

Alternatively, it is known from the prior art to use hard covering compositions, which surround the semiconductor chip and the wire connections on the carrier element, with a high modulus of elasticity. To increase the module bending resistance to neutralize the forces occurring in the region of the semiconductor chip and wires, it is also possible to use what is known as a hot-melt adhesive. The elastic properties of the latter, which can be further enhanced by a sandwich structure, effectively support the measures stated above. A further measure is that of introducing predetermined bending points and barriers against force introduction in the region of the semiconductor chip and wire connections. At the predetermined bending points, the carrier element buckles and consequently prevents tears in the wire connection or a rupture of the semiconductor chip.

### SUMMARY OF THE INVENTION

It is therefore the object of the present invention to specify a carrier element which is produced on a substrate and which provides great mechanical reliability, in particular under flexural loads acting on the carrier element. The carrier elements, formed on a nonconducting strip or a panel, are additionally intended to have an optimum layout configuration for high-volume processes.

This object is achieved according to claim 1 by a nonconducting substrate, forming a strip or a panel, on which a multiplicity of carrier elements are formed, intended in particular for incorporation in a chip card and respectively formed by a boundary line, which substrate has a contact side and an insertion side, lying opposite from the contact side, the insertion side being provided with a conducting insertion-side metallization which is formed in such a way that an electrical connection can take place by means of flip-chip bonding between the insertion-side metallization and contact points of an integrated circuit to be applied later to the insertion side.

The invention makes possible a contactless chip module which can be subjected to mechanical loading. The fact alone that flip-chip bonding known per se is provided instead of the customary electrical connection between the integrated circuit (semiconductor chip) and the insertion-side metallization by means of bonding wires considerably increases the mechanical load-bearing capacity, and consequently also the reliability, of a carrier element. In addition, the throughput rate during production can also be significantly increased, since all the electrical connections already can be established at one and the same time when the integrated circuit is applied to the insertion side of the substrate. In the case of a conventional electrical connection by means of bonding wires, on the other hand, each bonding wire has to be produced separately by a wire-bonding machine. Flip-chip bonding is also more stable mechanically than wire connections, since the solder agglomerations provided between the insertion-side metallization and the contact points of the integrated circuit can provide elastic compensation when flexural loads occur.

Within each boundary line, the insertion-side metallization has a plurality of contact elements, which are provided at least partly for bonding with flip-chip contacts of the integrated circuit. In other words, this means that, in one configuration, each contact element can be assigned to a contact point of the integrated circuit. However, it is preferred for there also to be contact elements which have no electrical connection with a contact point of the integrated circuit.

This allows the substrate to be mechanically stabilized by these contact elements. An increase in the module bending resistance is achieved by the non-contacted contact elements.

If a contact-side metallization is likewise provided on the contact side of the substrate, it is possible to realize a chip module of the purely with-contacts type or a hybrid chip module, which may also be connected via the insertion-side metallization to an antenna coil of a chip card.

It is preferred for the contact-side metallization to comprise within each boundary line a plurality of electrically isolated contact areas, which in a preferred configuration may be formed as ISO contact areas.

The contact areas of the contact-side metallization have at least partly an electrical connection with the contact elements of the insertion-side metallization, whereby a signal path is created between the externally accessible contact areas and the integrated circuit. The electrical connection is preferably established in each case by means of a plated-through hole reaching through the substrate.

The plated-through holes cannot be made here at any desired point of the contact areas or contact elements. This is because prescribed ISO standards have to be observed, and they prescribe a clearly defined area to be kept free. As a result, the position of the plated-through holes is restricted. The plated-through holes are therefore preferably arranged in each case in a plated-through region of the contact areas of the contact-side metallization which is not intended for bonding with an external reader (ISO zone).

In a preferred configuration, the contact-side metallization has within each boundary line regions which bring about an increased moment of resistance in the region of the integrated circuit applied later. These regions are preferably made in an area-covering form and extend at least over the length of a side edge of the integrated circuit. The regions bringing about an increased moment of resistance serve the purpose of defining predetermined bending lines within the carrier element. The predetermined bending lines in this case run outside the region in which the integrated circuit is arranged. The predetermined bending lines preferably extend parallel to the side edges of the integrated circuit.

To define these predetermined bending lines, the regions with an increased moment of resistance cross a line of symmetry, which is formed between the oppositely lying contact areas of the contact-side metallization.

The contact elements of the insertion-side metallization which are situated within the boundary lines are preferably made in the form of interconnects, which respectively have a first end and a second end. According to the invention, the first end of the interconnect overlaps with one of the plated-through holes and is in electrical connection with it. The second end, on the other hand, has a first contact area for the electrical bonding with a contact point of the integrated circuit.

In an advantageous configuration, at least some of the interconnects have at least a further contact area, which is in electrical contact with the first contact area of the interconnect either directly or via a portion of the interconnect connected to the first contact area, or which is in electrical contact with the interconnect via an interconnect branch, the further contact areas being respectively provided for the electrical bonding with a contact point of the integrated circuit. A contact element, preferably formed as an interconnect, of the insertion-side metallization may consequently have more than one contact area at or in the vicinity of the second end. However, usually only one of these contact areas is connected to a contact point of the integrated circuit.

The provision of a number of contact areas makes it possible for different contact point layouts of the integrated circuit to be taken into account. This allows the expenditure on logistics or storage to be kept low, since in principle only one substrate has to be provided to allow different integrated circuits to be connected. The two or more contact areas of a contact element may in this case be situated in direct proximity to one another, that is to say merge into one another and consequently form a contact area of a larger surface area. The contact areas may, however, also be spaced apart from one another and be in electrical connection with one another by means of an interconnect portion or an interconnect branch, that is to say a bifurcation of the interconnect.

A further development provides that the contact areas and the further contact areas of a contact element of the insertion-side metallization are designed in such a way that they serve as control marks when the integrated circuit is applied, in that the contact areas protrude slightly beyond the side edges of the integrated circuit. This makes it possible for the setting-down accuracy of the integrated circuit to be visually checked quickly, since in the case of a “proper” placement operation part of the contact area of a contact element always projects beyond the side edge of the integrated circuit. The contact areas are consequently made larger than is actually necessary. The larger contact area additionally increases at the same time the “hit area” for the contact point of the integrated circuit during the placement operation. At points at which this enlargement of the contact area is not possible, other metallization structures may also be introduced in addition to the contact areas of the contact elements.

A further development provides that at least some of the interconnects of the contact elements are provided with area-covering metallizations, which serve for increasing the bending rigidity of the substrate. Forming the contact elements as interconnects firstly has the effect that initially only a small part of the surface area within the boundary line which defines the carrier element is metallized. The larger the metallized area on the insertion side of the carrier element, the more rigid the carrier element becomes in flexural terms. As a result, it is ensured by this configuration that a substrate metallized to a greater or lesser extent on both sides is provided. The rigidity of a carrier element formed in such a way can, in addition, also be controlled by the thickness of the insertion-side metallization or contact-side metallization. The area-covering metallizations are in this case preferably formed within the respective boundary lines of a carrier element.

To avoid short-circuits, the area-covering metallizations, which are connected to the interconnects of the insertion-side metallization, are provided in a region outside the integrated circuit to be applied later.

A substrate on which the carrier elements are formed during production usually has indexing holes. To stiffen the substrate, the indexing holes are surrounded by metallizations on the insertion side and/or the contact side. This allows the handling of the substrates during production to be improved.

In an advantageous configuration, the substrate is additionally provided with adjusting marks for the orientation of placement machines, the adjusting marks constituting part of the insertion-side metallization and/or the contact-side metallization and preferably being situated in the region outside respective boundary lines. It is likewise conceivable for the adjusting marks to be connected to the contact areas of the contact-area metallization within respective boundary lines.

To increase the rigidity of the substrate further, and consequently for better handling, the substrate has between neighbouring carrier elements transverse webs which constitute part of the insertion-side metallization or contact-side metallization.

In a further advantageous configuration, in the region of the integrated circuit to be applied later, the insertion-side metallization comprises spacers which ensure plane-parallelism between the integrated circuit and the insertion side of the substrate. These spacers, which may likewise be part of the insertion-side metallization, but do not have to be, contribute to stopping the integrated circuit from bowing when the carrier element is applied. This likewise facilitates the application of the “underfill”, as it is known. During the curing of the underfill, which usually takes place under pressure, bowing is consequently likewise avoided.

In a further configuration, a stiffening frame is arranged on the insertion side of the substrate and surrounds the region intended for the integrated circuit to be applied later. The stiffening frame is preferably part of the insertion-side metallization, this frame having, in the region where it crosses or overlaps with contact elements of the insertion-side metallization, interruptions in order to avoid short-circuits. However, it is also conceivable for the stiffening frame to consist of a nonconducting material and for the region of the integrated circuit to be completely surrounded.

The substrate usually comprises an epoxy carrier strip. These have a thickness of 110 μm, onto which the adhesive is then applied and the metallization(s) is/are applied on top. By metallizing on both sides, the substrate becomes very rigid, but also relatively expensive. Therefore, the substrate preferably consists of PEN, PET, PI or paper, which according to the configurations presented above is metallized and possibly provided with plated-through holes. When one of the aforementioned materials is used, the insertion-side metallization and contact-side metallization need not be laminated on, but can instead be grown on. This makes it possible to dispense with an adhesive and to make the metallizations much thinner. A contact-side and insertion-side metallization produced by a growing-on process makes it possible to obtain a thickness of less than 5 μm. The thickness of the substrate with one of the above materials is then preferably approximately 50 or 70 μm. However, it goes without saying that other thicknesses are also possible, if this is advantageous for handling. The substitution of the epoxy carrier substrate makes it possible overall to obtain a much thinner carrier element.

The substitution of the epoxy substrate by other materials is only made possible by flip-chip bonding, since in this case maximum processing temperatures of around 140° C. occur, whereas in the case of conventional chip modules, which use electrical connection by means of bonding wires, temperatures of around 230° C. occur. Consequently, it is only the use of flip-chip technology that makes it possible to use more recent, less costly materials, which is of great significance, in particular in a high-volume production process.

### BRIEF DESCRIPTION OF THE DRAWINGS

The invention is explained in more detail below on the basis of several exemplary embodiments with the aid of figures, in which:

FIG. 1 shows the contact-side view of a detail from a substrate strip in a first exemplary embodiment,

FIG. 2 shows the insertion-side view of a detail of a substrate strip according to the first exemplary embodiment,

FIG. 3 shows the contact-side view of a detail from a substrate strip according to a second exemplary embodiment,

FIG. 4 shows the insertion-side view of a detail from a substrate strip according to the second exemplary embodiment,

FIG. 5 shows a more detailed representation of the contact side of a carrier element according to the second exemplary embodiment,

FIG. 6 shows a more detailed view of the insertion side of a carrier element according to the second exemplary embodiment,

FIG. 7 shows the contact-side view of a detail from a substrate strip of a third exemplary embodiment,

FIG. 8 shows the insertion-side view of a detail from a substrate strip according to the third exemplary embodiment,

FIG. 9 shows a more detailed representation of the insertion side of a carrier element according to the third exemplary embodiment and

FIG. 10 shows a more detailed representation of the insertion side of a carrier element of a fourth exemplary embodiment.

### DETAILED DESCRIPTION OF THE PREFERRED MODE OF THE INVENTION

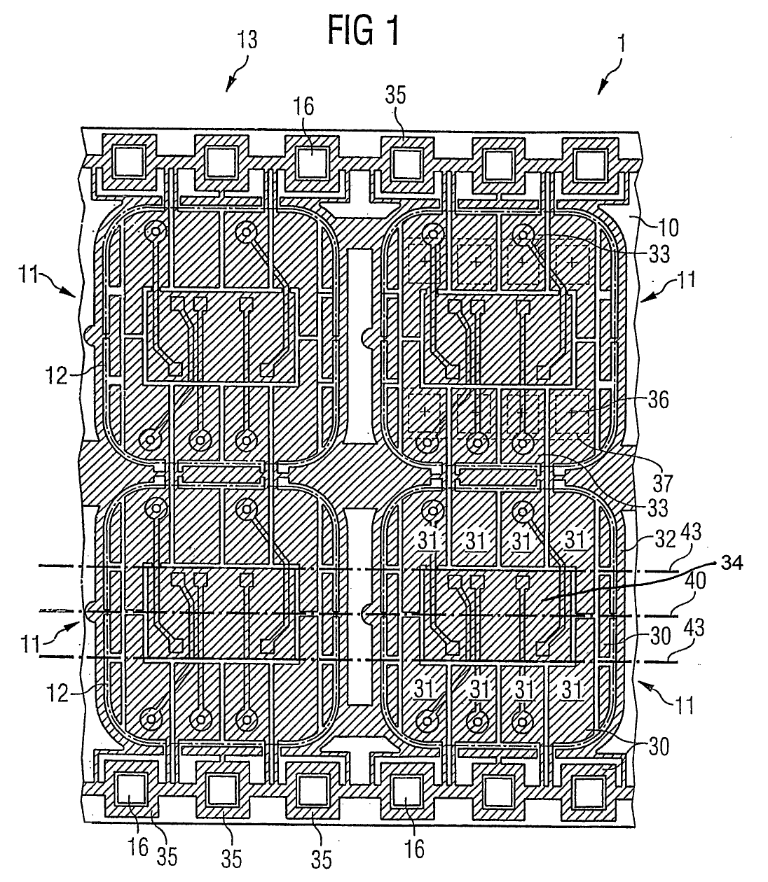

FIG. 1 shows a detail from a strip 1, on which four carrier elements 1 are formed in pairs. However, it is possible to arrange a larger number than two carrier elements 11 next to one another on the strip 1. The strip 1 consists of a nonconducting substrate 10, it being possible to use for example glass-fibre-reinforced epoxy resin, PEN, PET, PI or paper as the material. Use of the latter materials has the advantage that they have a thickness reduced by half in comparison with epoxy resin.

The substrate 10 has indexing holes 16 along both edges, which serve for further transport by means of drivers engaging in the indexing holes 16, for example during the placement of integrated circuits onto the strip. The outer contour of each carrier element 11 is respectively indicated by a dash-dotted boundary line 12. Once component placement on them has been completed, the carrier elements are punched out of the strip 1, or cut out in some other way, along these boundary lines 12.

The present FIG. 1 shows the contact side of the substrate 10. The nonconducting substrate 10 is laminated for example with a metal foil, preferably a copper foil. By subsequent etching, this metal foil is structured, so that contact areas 31 within the boundary lines 12 and further contact areas, which lie outside the boundary line 12 of the carrier element, are produced. The contact areas 31 and the further contact areas are all connected to one another in a known way by means of narrow lines. This electrical short-circuit is necessary when the contact areas 31 and the further contact areas undergo electroplating surface treatment.

When PEN, PET, PI or paper is used as the substrate material instead of epoxy resin, the contact areas 31 need not be laminated on, but instead can be applied in a growing-on process. For this purpose, firstly a metal layer a few nanometres thick, for example of copper, is sputtered onto the substrate. After the punching of the plated-through holes, consolidation by an electroplating process takes place, so that the metallization initially provided over the full surface area has a thickness of several μm. In the next step, the metallization is structured in the desired form and subjected to electroplating surface treatment, for example with nickel and copper. The electroplating surface treatment could also be performed in a currentless process, whereby an electrical short-circuit is not necessary between the contact areas and the further contact areas. The procedure according to the invention makes it possible to dispense with the use of adhesive for applying the metallization. Moreover, the contact-side metallization can be made much thinner, making cost savings possible. The contact-side metallization then usually has only a thickness of less than 40 μm. The substrate or the thickness of the substrate can be adapted to handling needs. Customary substrate thicknesses are 50 to 125 μm, although it goes without saying that other thicknesses are possible.

Provided around the indexing holes 16 are metallizations 35, which are respectively connected to one another by a web. The metallizations 35 contribute to improving the rigidity, and consequently the handling, of the substrate 10 or of the strip 1.

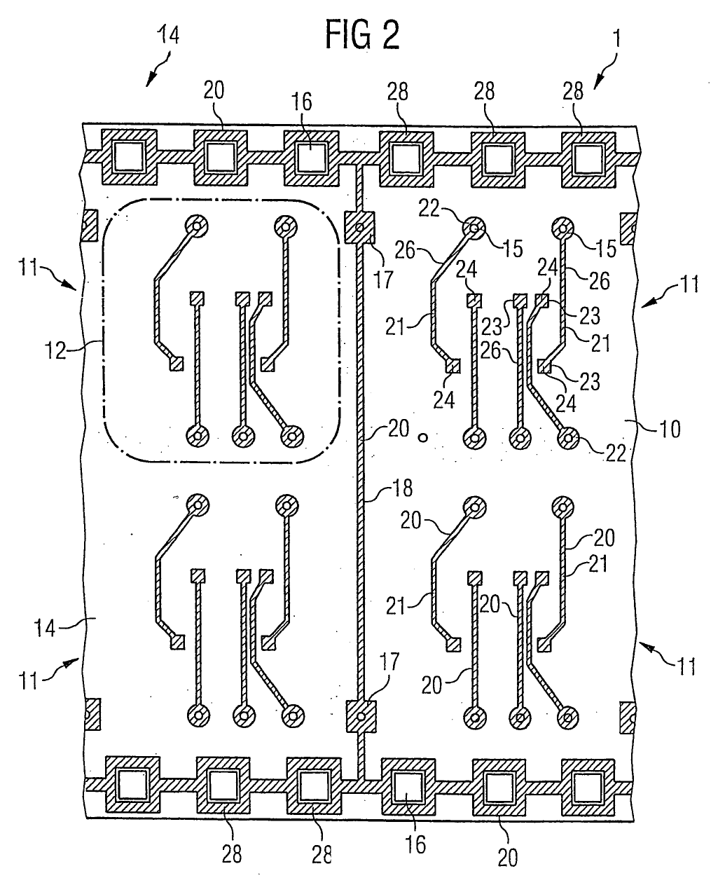

FIG. 2 shows the other side (that is the insertion side) of the substrate 10, on which the integrated circuit (not represented) is mounted. The insertion-side metallization 20, which is applied on the insertion side 14 and comprises the conductor structures 26, 24, 22, 28, 17, 18, can be produced by laminating with metal foils and etching. Alternatively, as already described in relation to FIG. 1, the insertion-side metallization may also be produced by a growing-on process.

The substrate 10 is relatively flexible. In a chip card, an integrated circuit mounted on it would be subjected to considerable flexural loads. Relatively large semiconductor chips could even break. For this reason, a reinforcing frame (not represented in FIG. 2) is applied on the insertion side of the carrier element around the region of the integrated circuit. The reinforcing frame is preferably made of metal, but it may also consist of some other material. Since the carrier elements are usually adhesively bonded into the chip card, there must be space for the adhesive along the edge of the carrier elements, so that the reinforcing frame runs just outside the region of the contact areas 24 which constitute part of the insertion-side metallization 20. A corresponding exemplary embodiment is represented in FIG. 10.

Special structural configurations of the insertion-side metallization and contact-side metallization are discussed below.

The insertion-side metallization has a plurality of contact elements 21, which in the present exemplary embodiment according to FIG. 2 are respectively provided for later electrical bonding with contact points of the integrated circuit. The contact elements 21 are made in the form of interconnects 26 with in each case a first end 22 and a second end 23. The first end 22 has, by way of example, in each case an annular shape, the centre of which is connected to a plated-through hole. In principle, the first end 22 could be of any desired form, for example rectangular, ellipsoid, polygonal, etc. The plated-through hole 15 extends through the substrate to corresponding contact areas 31. The second ends 23 are respectively provided with a contact area 24, here of an approximately square form. The arrangement of the contact areas 24 in this case corresponds to the arrangement of the contact point of the semiconductor chip not shown here.

The way in which the contact elements of the insertion-side metallization are arranged in relation to the contact areas 31 of the contact-side metallization is revealed by FIG. 1. In the present example, the contact areas 24 of the insertion-side metallization come to lie in a central region 34, formed as a contact area, of the contact-side metallization. In this central region, the integrated circuit (which cannot be seen from FIG. 1) is arranged (on the insertion side).

In the upper, right carrier element of FIG. 1, the regions 37 defined by an ISO standard can be seen. Within the area identified by the reference numeral 37, the contact pins of a reader come to lie. The regulations stipulate that the region taken up by the ISO zone 37 must be free from plated-through holes. Consequently, only those regions of each contact area 31 which are situated outside the ISO zone 37 come into consideration as plated-through regions 33. In the present exemplary embodiment of FIG. 1, the plated-through regions 33 are located close to the boundary line 12, when viewed from the contact area 31. However, it is to be preferred if the plated-through region 33 is situated in the direction of the central region 34, when viewed from the contact area 31.

The contact-side metallization additionally has regions 32 which bring about an increased moment of resistance in the region of the integrated circuit to be mounted later. As a result, the bending rigidity of the carrier element 11 is increased. The regions 32 are in this case designed in such a way that they are approximately of the same width as the central region 34. The regions 32 in this case extend over a line of symmetry 40 of the carrier element 11. The fact that the width of the regions 32 approximately coincides with the width of the central region 34 means that there are two predetermined bending lines 43 running parallel to the line of symmetry 40 and along which the carrier element can buckle under excessive flexural loading. This ensures that no flexural loads act on the integrated circuit.

The metallizations 17, 18, 28, which are part of the insertion-side metallization, advantageously serve for stabilizing the substrate 10. The metallizations 28 surround the indexing holes 16 and are connected to one another via webs. In the present exemplary embodiment, transverse webs 18 run between neighbouring carrier elements 11 and extend along the edges of the strip 1. Adjusting marks 17 constitute part of the transverse webs 18. The transverse webs 18 have no further function apart from stabilization, whereas the adjusting marks 17 can be used for optical recognition systems. In the present exemplary embodiment, the adjusting marks 17 are formed as squares. Depending on the recognition system, the adjusting marks could also be designed as crosses, circles, rectangles or in some other form. The adjusting marks 17 also do not necessarily have to constitute part of the transverse webs 18.

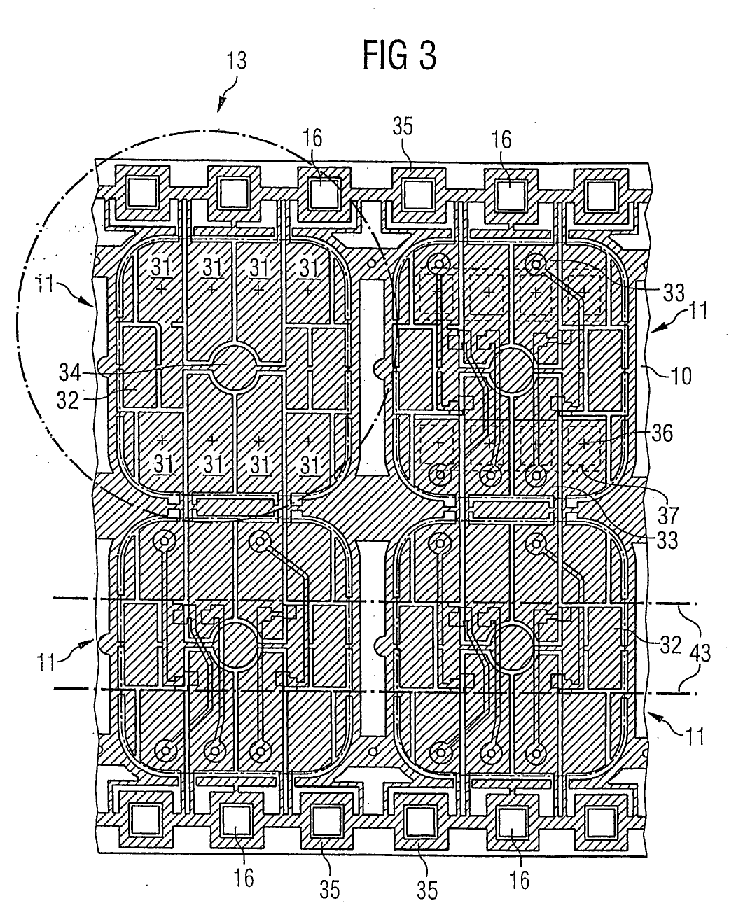

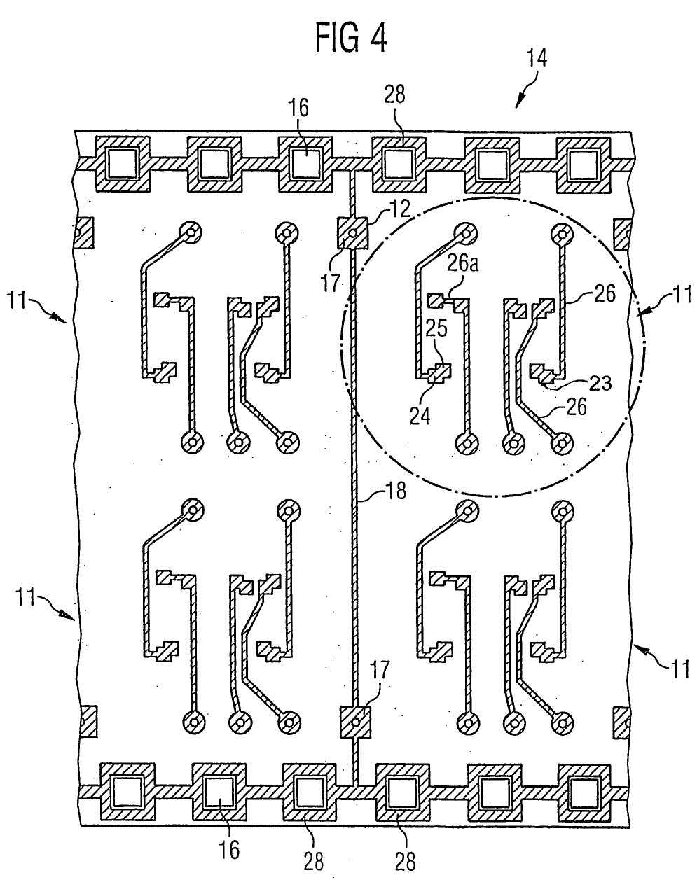

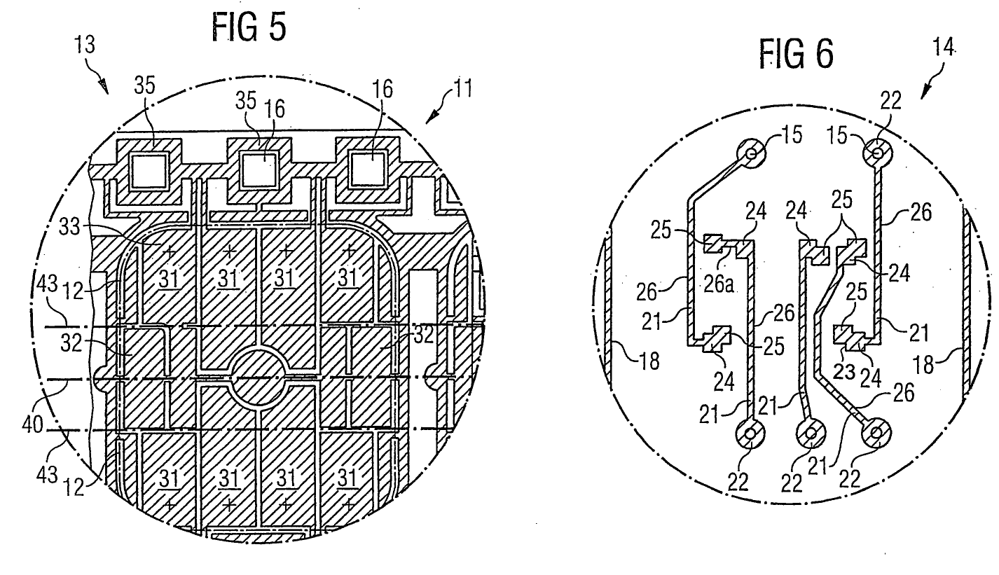

FIGS. 3 and 4 show a second exemplary embodiment, with a detail from the contact side of the substrate being shown in FIG. 3, while a detail from the insertion side of the substrate is represented in FIG. 4. FIGS. 5 and 6 respectively show the contact-side view and insertion-side view of a carrier element according to the second exemplary embodiment in an enlarged representation. The contact-side metallization of the second exemplary embodiment differs from that of the first example in that the central region 34 is not formed as a rectangle which takes up a larger surface area than the integrated circuit. Rather, in the present exemplary embodiment, the central region 34 is of a circular form and takes up a smaller surface area than the integrated circuit to be applied on the insertion side. This configuration has the advantage that the contact areas 31 may have a larger surface area in the direction of the central region, which can then be used as a plated-through region. In addition, the regions 32 are enlarged with an increased moment of resistance. The enlargement in this case concerns a greater extent in the direction of the central region, whereby the module bending resistance of the carrier element is increased. The width of the region 32 of FIG. 3 corresponds to the width in FIG. 1, with predetermined bending lines 43 being defined by the ends. When there is bowing of the carrier element 4 or of the chip module, the central contact areas 31 are indeed bent, but the integrated circuit lies in a region within the predetermined bending lines 43 and is therefore protected.

As can be seen from the upper, right carrier element 11 of FIG. 3, the contact areas 31 satisfy the requirements of ISO standard 7816-2. The arrangement of the ISO zones 37 and the positions 36 at which the contact pins of the reader meet the contact areas 31 correspond to the configuration of FIG. 1.

The configuration of the insertion-side metallization of the second exemplary embodiment substantially corresponds to the configuration of the first exemplary embodiment. The insertion-side metallization differs, however, in that the second ends 23 of the interconnects 26 respectively have a further contact area 25, as can be seen well from FIG. 6. The contact area 24 and the contact area 25 may in this case merge with each other or be in connection with each other via an interconnect portion 26. The contact areas 24 correspond to the layout of the contact points of a first integrated circuit, while the arrangement of the further contact points 25 corresponds to the layout of the contact points of a further integrated circuit. Consequently, it is possible with a single substrate to take into account the contact point layout of different integrated circuits. In principle, it would also be conceivable to use the contact areas 24 or the further contact areas 25 as bonding pads.

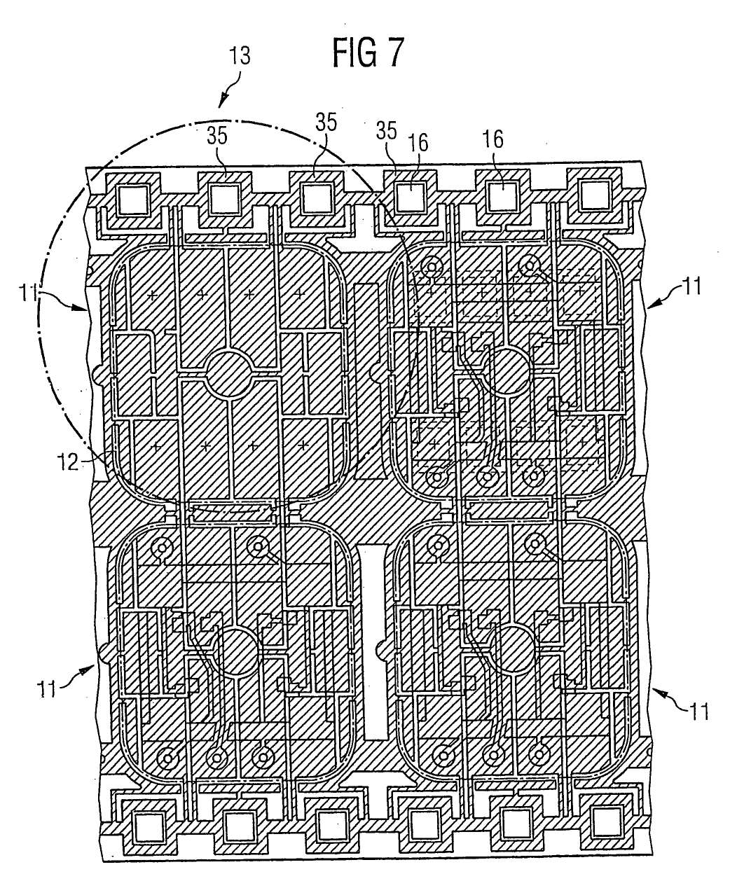

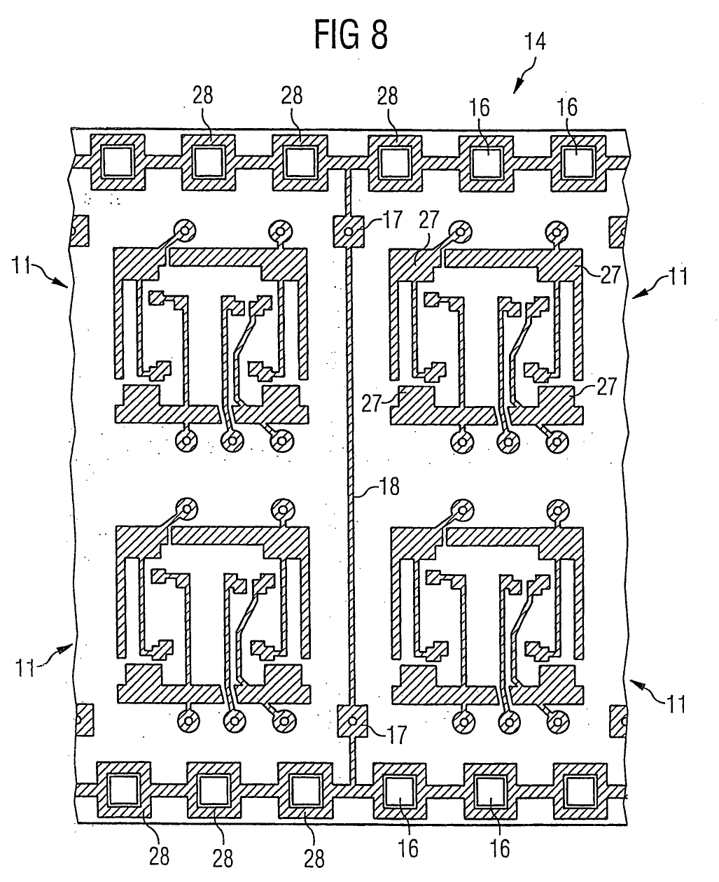

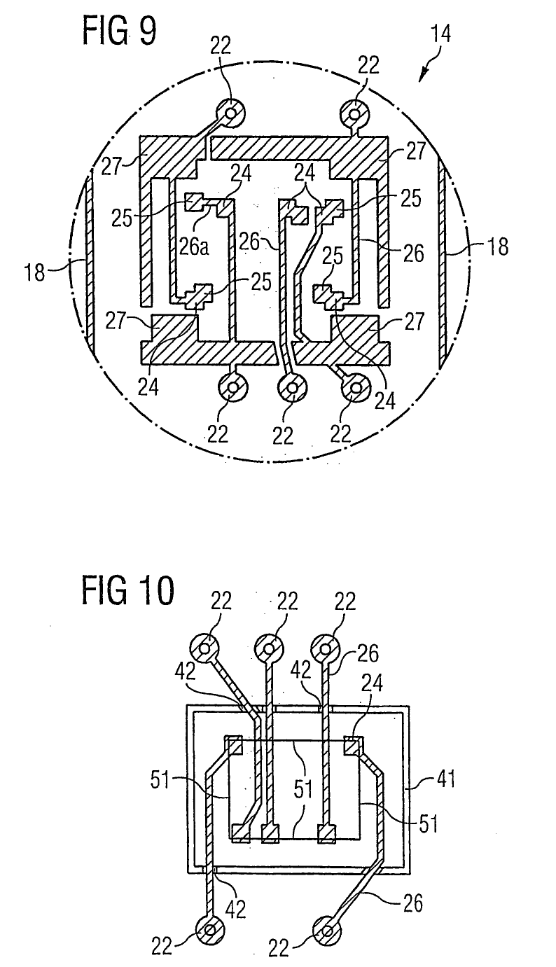

FIGS. 7 and 8 respectively show the contact-side view and insertion-side view of a carrier substrate according to a third exemplary embodiment, the layout of the insertion-side metallization being shown enlarged in FIG. 9. The layout of the contact-side metallization according to FIG. 7 corresponds here to the layout of the contact-side metallization of the second exemplary embodiment according to FIGS. 3 and 5.

The insertion-side metallization according to FIG. 8 represents an extension of the layout of the second exemplary embodiment according to FIG. 6. The interconnects 26 are provided here with area-covering metallizations 27, which take up a large part of the surface area of a carrier element 11. Only the region in which the integrated circuit is to be applied has been cut out from the area-covering metallizations 27. The arrangement of the contact areas 24 and of the further contact areas 25 otherwise corresponds to the arrangement from the second exemplary embodiment according to FIG. 6. It goes without saying that the area-covering metallizations 27 of respective interconnects 26 have no electrical contact with one another. The area-covering metallizations 27 primarily serve for further increasing the rigidity of the carrier element. The metallization on both sides of the substrate 10 produces a greater rigidity, which makes it possible to use a thinner substrate material, for example of PEN, PET, PI or paper.

As already stated further above, these materials make it possible to allow the metallizations to grow on, and to dispense with the use of adhesive for the connection of the metallization and the substrate.

FIG. 10, finally, shows part of the insertion-side metallization, from which the arrangement of a stiffening frame 41 can be seen. As shown in the present example, the stiffening frame 41 may be part of the insertion-side metallization. At the points at which it crosses interconnects or regions of the contact elements 21, the stiffening frame 41 has interruptions 42 to avoid short-circuits. A further reinforcing frame could be mounted on the stiffening frame 41.

The attachment could take place for example by means of a nonconducting adhesive.

In addition, it can be seen from FIG. 10 how the contact areas 24 may serve as control marks when the integrated circuit is applied. The side edges of an integrated circuit to be applied later are identified by the reference numeral 51. If the integrated circuit is optimally applied to the substrate, part of the contact areas 24 always projects beyond the side edges 51, in the way represented in FIG. 10. Ideally, the side edges 51 of the integrated circuit and the edges of the contact areas are aligned parallel to one another. It is consequently possible to carry out a visual check to ascertain whether the flip-chip bonding of the integrated circuit with the contact areas of the insertion-side metallization has correctly taken place.

What is claimed is:

1. A nonconducting substrate forming a strip or a panel on which a plurality of carrier elements having respective boundary lines are formed, comprising:
a contact side;
an insertion side opposite the contact side; and
a conducting insertion-side metallization provided on the insertion side;
wherein the insertion-side metallization is formed such that an electrical connection can take place by means of flip-chip bonding between contact points of an integrated circuit to be applied to the insertion side and the insertion-side metallization.

2. The substrate according to claim 1, further comprising a plurality of contact elements provided on the insertion-side metallization within each boundary line at least partly for bonding with flip-chip contacts of the integrated circuit.

3. The substrate according to claim 1, further comprising a contact-side metallization provided on the contact side of the substrate.

4. The substrate according to claim 3, further comprising a plurality of contact areas which are electrically isolated from one another and are provided on the contact-side metallization within each boundary line.

5. The substrate according to claim 4, wherein the contact areas of the contact-side metallization are formed as ISO contact areas.

6. The substrate according to claim 4, further comprising:
a plurality of contact elements provided on the insertion-side metallization within each boundary line at least partly for bonding with flip-chip contacts of the integrated circuit,
wherein the contact areas of the contact-side metallization have at least partly an electrical connection with the contact elements of the insertion-side metallization.

7. The substrate according to claim 6, wherein the electrical connection is established by plated-through holes extending through the substrate.

8. The substrate according to claim 7, wherein the plated-through holes are each arranged in a plated-through region of the contact areas of the contact-side metallization which is not intended for bonding with an external reader (ISO zone).

9. The substrate according to claim 3, further comprising a boundary line region which includes the contact-side metallization and brings about an increased moment of resistance in a region of the integrated circuit.

10. The substrate according to claim 9, wherein the boundary line region crosses a line of symmetry, which is formed between oppositely lying contact areas of the contact-side metallization.

11. The substrate according to claim 2, wherein the contact elements of the insertion-side metallization are in a form of interconnects, which respectively have a first end and a second end.

12. The substrate according to claim 7, wherein the contact elements of the insertion-side metallization are in a form of interconnects, which respectively have a first end and a second end, the first end of the interconnects overlapping with a respective one of the plated-through holes and being in electrical connection therewith.

13. The substrate according to claim 11, wherein the second end has a first contact area for the electrical bonding with a flip-chip contact of the integrated circuit.

14. The substrate according to claim 13, wherein at least some of the interconnects have at least a further contact area, which is in electrical contact with the first contact area of the interconnect either directly or via a portion of the interconnect connected to the first contact area, the respective further contact areas being provided for the electrical bonding with a flip-chip contact of the integrated circuit.

15. The substrate according to claim 11, wherein at least some of the interconnects have at least a farther contact area, which is in electrical contact with the interconnect via an interconnect branch, the respective further contact areas being provided for the electrical bonding with a flip-chip contact of the integrated circuit.

16. The substrate according to claim 14, wherein the contact areas and the further contact areas serve as control marks when the integrated circuit is applied, in that the contact areas protrude slightly beyond side edges of the integrated circuit.

17. The substrate according to claim 15, wherein the contact areas and the further contact areas serve as control marks when the integrated circuit is applied, in that the contact areas protrude slightly beyond side edges of the integrated circuit.

18. The substrate according to claim 11, wherein at least some of the interconnects are provided with area-covering metallizations, which serve for increasing the bending rigidity of the substrate.

19. The substrate according to claim 18, wherein the area-covering metallizations are formed within the boundary line of the respective carrier element.

20. The substrate according to claim 18, wherein the area-covering metallizations are provided in a region outside the integrated circuit to be applied.

21. The substrate according to claim 1, further comprising indexing holes, which are provided on the substrate, and to stiffen the substrate, are surrounded by metallizations on the insertion side and/or the contact side.

22. The substrate according to claim 3, further comprising adjusting marks which constitute part of the insertion-side metallization and/or the contact-side metallization and are provided on the substrate for orientation of placement machines.

23. The substrate according to claim 3, further comprising transverse webs which constitute part of the insertion-side metallization and/or contact-side metallization and are provided on the substrate between neighbouring carrier elements.

24. The substrate according to claim 1, wherein, in a region of the integrated circuit to be applied, the insertion-side metallization comprises spacers which ensure plane-parallelism between the integrated circuit and the insertion side of the substrate.

25. The substrate according to claim 1, further comprising a stiffening frame arranged on the insertion side of the substrate and surrounding a region intended for the integrated circuit to be applied.

26. The substrate according to claim 25, wherein the stiffening frame is part of the insertion-side metallization.

27. The substrate according to claim 25, wherein the stiffening frame has, in a region where it crosses or overlaps with contact elements of the insertion-side metallization, interruptions in order to avoid short-circuits.

28. The substrate according to claim 26, wherein the stiffening frame consists of a nonconducting material.

29. The substrate according to claim 28, wherein the stiffening frame completely surrounds the region intended for the integrated circuit to be applied.

30. The substrate according to claim 1, wherein the substrate consists of at least one of PEN, PET, PI, and paper.

31. The substrate according to claim 30, wherein the thickness of the substrate is approximately 50 to 125 μm.

32. The substrate according to claim 3, wherein the contact-side metallization and the insertion-side metallization are produced by a growing-on process.

33. The substrate according to claim 32, wherein the contact-side metallization and the insertion-side metallization have a thickness of less than 40 μm.
